(19) United States
(12) Patent Application Publication
(10) Pub. No.: US 2023/0066965 A1
(43) Pub. Date: Mar. 2, 2023

(54) MOUNTING ASSEMBLY FOR ELECTRICAL BOX

(71) Applicant: NINGBO WELL ELECTRIC APPLIANCE CO., LTD., Ningbo (CN)

(72) Inventor: Guolin YU, Ningbo (CN)

(21) Appl. No.: 17/542,483

(22) Filed: Dec. 5, 2021

(30) Foreign Application Priority Data
Sep. 1, 2021 (CN) 202122099424.6

(51) Int. Cl. H05K 7/14

(52) U.S. Cl. CPC H05K 7/1417; H05K 7/1438

(57) ABSTRACT

A mounting assembly for an electrical box is provided, which includes a power socket, a bracket and a connecting member. The connecting member is configured to act on the bracket and the electrical box to restrictively mount the bracket on the electrical box. The bracket is provided with a plurality of connecting protrusions at intervals. The socket box is provided with a groove, and the plurality of connecting protrusions are corresponding to the groove. The connecting member is mounted on the groove of the electrical box, and a part of the connecting member in the groove successively penetrates through the plurality of connecting protrusions.

### CROSS-REFERENCE TO RELATED APPLICATIONS

This application claims all benefits accruing under 35 U.S.C. § 119 from China Patent Application No. 202122099424.6, filed on Sep. 1, 2021, in the China National Intellectual Property Administration, the content of which is hereby incorporated by reference.

### TECHNICAL FIELD

The present disclosure relates to an electrical box, and in particular, to a mounting assembly for an electrical box for a power socket.

### BACKGROUND

An electrical box or junction box is configured to accommodate a power socket. The electrical box commonly cooperates with a bracket, and is fixed on a wall via the bracket.

Currently, the electrical box and the bracket are commonly connected via a long bolt. Specifically, a trapezoidal protrusion is provided on an end surface of the bracket attached to the electrical box, and a groove matching with the protrusion is disposed on the electrical box. The long bolt mounted on the electrical box penetrates through the protrusion to restrictively mount the bracket on the electrical box. Therefore, the long bolt can drive the bracket to move relative to the electrical box, so that the bracket is adjustably mounted on the electrical box. However, the bracket is entirely in a board shape, but the protrusion is in a block shape, thus the bracket is hard to produce. In addition, the long bolt should be aligned with a threaded hole in the protrusion and spirally penetrate through the protrusion, and it is hard to restrictively mount the bracket on the electrical box by the long bolt.

### SUMMARY

In view of this, it is necessary to provide a mounting assembly for an electrical box in response to the technical problems in conventional art.

The present disclosure provides a mounting assembly for an electrical box, including a power socket, a bracket and a connecting member, the connecting member is configured for mounting the bracket on the electrical box.

The bracket is provided with a plurality of connecting protrusions at intervals. The electrical box is provided with a groove corresponding to the plurality of connecting protrusions. The connecting member is accommodated in the groove of the electrical box, and a part of the connecting member in the groove successively penetrates through the plurality of connecting protrusions and is detachably fixed with the plurality of connecting protrusions.

In the present disclosure, by penetrating the connecting member through the plurality of connecting protrusions disposed at intervals, the bracket is restrictively mounted on the electrical box. A structure of the mounting assembly is simplified, which facilitates mounting the bracket on the electrical box with the connecting member. In addition, the bracket is fitted with the electrical box and the connecting member via the plurality of connecting protrusions, and production of the bracket is more convenient.

In some embodiments, the connecting member is provided with a thread protrusion. The connecting member is capable of driving the bracket to reciprocate relative to the electrical box by a cooperation between the plurality of connecting protrusions and the thread protrusion.

It could be understood that since the thread protrusion on the connecting member matches with the plurality of connecting protrusions, the connecting member can drive the bracket to move relative to the electrical box, thereby facilitating adjusting a position of the bracket on the electrical box during the mounting assembly working.

In some embodiments, the bracket is provided with a limiting protrusion between adjacent two of the plurality of connecting protrusions. Both the limiting protrusion and the plurality of connecting protrusions abut against and surround the connecting member.

It should be understood that, the connecting member is connected to the bracket via the limiting protrusion, to improve assembly stability between the connecting member and the bracket. In addition, since the bracket is fitted with the connecting member via a cooperation between the plurality of connecting protrusions and the limiting protrusions, a contact area between the bracket and the connecting member can be reduced, so that a frictional resistance of the connecting member when driving the bracket to move on the electrical box can be decreased.

In some embodiments, the plurality of connecting protrusions are a plurality of protruding plates, and the plurality of protruding plates are integrated with the bracket.

It should be understood that since the plurality of connecting protrusions are integrated with the bracket, a structure of the bracket is simple, which facilitates producing the bracket.

In some embodiments, the number of the plurality of connecting protrusions is two.

It should be understood that by designing two connecting protrusions, the structure of the bracket is simplified on the premise that the bracket is restrictively mounted on the electrical box via fitting between the connecting member and the bracket, thereby further facilitates producing the bracket.

In some embodiments, the bracket includes a body plate, the plurality of connecting protrusions are disposed on the body plate. The body plate extends towards a direction away from the electrical box and defines a fixing plate, wherein the fixing plate is provided with a fixing hole.

It should be understood that by designing the bracket provided with the fixing plate having the fixing hole, the bracket can be fixed to a wall via the fixing hole on the fixing plate.

In some embodiments, the fixing plate extends towards a direction away from the plurality of connecting protrusions and defines two hook plates, wherein the two hook plates are located at two sides of the fixing plate, respectively.

It should be understood that, the bracket can be fastened to the wall or a fixture on the wall via the hook plate, which facilitates fixing the bracket on the wall.

In some embodiments, the body plate extends outwards relative to the electrical box and defines two mounting protrusions. The two mounting protrusions are located at both sides of the electrical box, respectively, and wherein each of the two mounting protrusions is provided with a connecting hole.

It should be understood that, the bracket can also be fixed to the wall with the two mounting protrusions, which further facilitates fixing the bracket on the wall.

In some embodiments, the groove on the electrical box includes an annular shaped portion, wherein the connecting member rotatably penetrates through the annular shaped portion, and the connecting member comprise two shrink rings corresponding to the annular shaped portion, to limit a position of the connecting member relative to the annular shaped portion.

It should be understood that by designing the groove having the above structure, the connecting member can be connected to the electrical box, so that the connecting member can rotate relative to the electrical box when the mounting assembly works.

In some embodiments, the electrical box is provided with two sliding grooves, the bracket is provided with two slipping sheets corresponding to the two sliding grooves, and the bracket is slidably mounted on the electrical box via fitting between the two slipping sheets and the two sliding grooves.

It should be understood that by designing the electrical box having two sliding grooves and two slipping sheets, the bracket can be slidably fitted with the electrical box, so that the bracket can move relative to the electrical box, thereby meeting a requirement of adjusting a mounting position between the bracket and the electrical box.

### BRIEF DESCRIPTION OF THE DRAWINGS

FIG. 1 is a structural schematic diagram of a mounting assembly for an electrical box in the present disclosure.

FIG. 2 is an exploded view of a mounting assembly for an electrical box in the present disclosure.

FIG. 3 is a structural schematic diagram of an electrical box in the present disclosure.

FIG. 4 is a structural schematic diagram of a bracket in the present disclosure.

FIG. 5 is a structural schematic diagram of a connecting member in the present disclosure.

In the figures, 10 represents an electrical box; 11 represents a groove; 12 represents an annular shaped portion; 20 represents a bracket; 21 represents a connecting protrusion; 22 represents a limiting protrusion; 30 represents a connecting member; 31 represents a thread protrusion; 32 represents a shrink ring; 101 represents a chute; 102 represents a slipping sheet; 201 represents a body plate; 202 represents a fixing plate; 2021 represents a fixing hole; 203 represents a hook plate; 204 represents a mounting protrusion; 2041 represents a connecting hole.

### DETAILED DESCRIPTION

The technical solutions in the embodiments of the present disclosure will be clearly and completely described below in conjunction with the drawings in the embodiments of the present disclosure. Obviously, the described embodiments are only a part of the embodiments of the present invention, rather than all the embodiments. Based on the embodiments of the present disclosure, all other embodiments obtained by those of ordinary skill in the art without creative work shall fall within the protection scope of the present disclosure.

Unless otherwise defined, all technical and scientific terms used herein have the same meaning as one of ordinary skill in the art would understand. The terminology used in the description of the present disclosure is for the purpose of describing particular embodiments and is not intended to limit the disclosure.

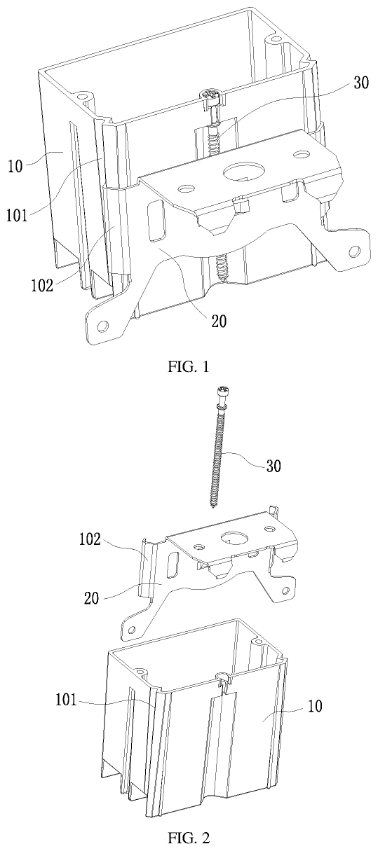

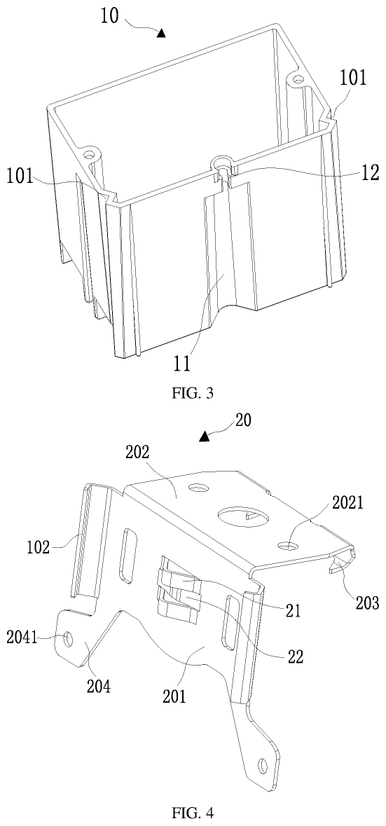

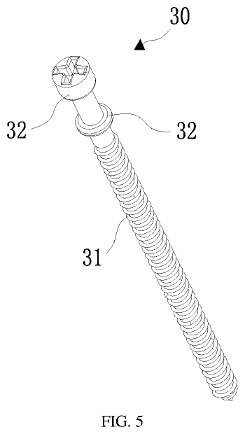

Referring to FIG. 1 to FIG. 5, the figures show a mounting assembly for an electrical box in an embodiment of the present disclosure, which can include an electrical box 10, a bracket 20 and a connecting member 30.

The connecting member 30 can be configured for mounting the electrical box 10.

In the present embodiment, the bracket 20 can be provided with a plurality of connecting protrusions 21 at intervals. The electrical box 10 can be provided with a groove 11 corresponding to the plurality of connecting protrusions. The connecting member 30 can be accommodated in the groove 11 of the electrical box 10, and a part of the connecting member 30 in the groove 11 can successively penetrate through the plurality of connecting protrusions 21 to restrictively mount the bracket 20 on the electrical box 10. It should be illustrated that according to actual requirements, the plurality of connecting protrusions 21 can be attached to an inner wall of the groove 11, or can leave a preset between the inner wall of the groove 11, which will not be illustrated in details herein.

It should be understood that in the present disclosure, by penetrating the connecting member 30 through the plurality of connecting protrusions 21 disposed at intervals, the bracket 20 can be restrictively mounted on the electrical box 10. A structure of the mounting assembly can be simplified, which can facilitate mounting the bracket 20 on the electrical box 10 with the connecting member 30. In addition, the bracket 20 can be fitted with the electrical box 10 and the connecting member 30 via the plurality of connecting protrusions 21, and production of the bracket 20 can be more convenient.

In the present embodiment, the connecting member 30 can be provided with a thread protrusion 31. The connecting member 30 can drive the bracket to reciprocate relative to the electrical box by cooperation between the plurality of connecting protrusions 21 and the thread protrusion 31. Therefore, the connecting member 30 can drive the bracket 20 to move on the electrical box 10 by means of screwing the connecting member 30, thereby facilitating adjusting a position of the bracket 20 on the electrical box 10 during the mounting assembly working. It should be illustrated that the thread protrusion 31 can be a convex thread structure.

In the present embodiment, the bracket 20 can be provided with a limiting protrusion 22 between adjacent two connecting protrusions 21 of the plurality of connecting protrusions 21. Both the limiting protrusion 22 and the plurality of connecting protrusions 21 can abut against and surround the connecting member 30. Therefore, the connecting member 30 can be connected to the bracket 20, and assembly stability between the connecting member 30 and the bracket 20 can be further improved. In addition, since the bracket 20 can be fitted with the connecting member 30 via the plurality of connecting protrusions 21 and the limiting protrusions 22, a contact area between the bracket 20 and the connecting member 30 can be reduced, so that a frictional resistance of the connecting member 30 when driving the bracket 20 to move on the electrical box 10 can be reduced.

In the present embodiment, the plurality of connecting protrusion protrusions 21 can be a plurality of protruding plates, and the plurality of protruding plates can be integrated with the bracket 20. Therefore, a structure of the bracket 20 can be simple, which can facilitate producing the bracket 20.

In the present embodiment, the number of the plurality of connecting protrusions 21 can be two. On the premise that the bracket 20 can be restrictively mounted on the electrical box 10 via fitting between the connecting member 30 and the bracket 20, the structure of the bracket 20 can be simplified, thereby can further facilitate producing the bracket 20. The number of the plurality of connecting protrusions 21 can be not limited to two. The number of the plurality of connecting protrusions 21 can be three, four or more for one of ordinary skill in the art.

In the present embodiment, the bracket 20 can include a body plate 201, and the plurality of connecting protrusions 21 can be disposed on the body plate 201. The body plate 201 can extend towards a direction away from the electrical box 10 and define a fixing plate 202, wherein the fixing plate 202 can be provided with a fixing hole 2021. Therefore, by designing the bracket 20 provided with a fixing plate 202 having a fixing hole, the bracket 20 can be fixed to a wall via the fixing hole 2021 on the fixing plate 202.

In addition, the fixing plate 202 can extend towards a direction away from the plurality of connecting protrusions 21 and define two hook plates 203, wherein the two hook plates 203 can be located at two sides of the fixing plate 202, respectively. Therefore, the bracket 20 can be clamped to the wall or a fixture on the wall, which can facilitate fixing the bracket 20 on the wall.

Furthermore, the body plate 201 can extends outwards relative to the electrical box and define two mounting protrusions 204. The two mounting protrusions 204 can be located at both sides of the electrical box 10, respectively, and wherein each of the two mounting protrusions 204 can be provided with a connecting hole 2041. Therefore, the bracket 20 can also be fixed to the wall with the two mounting protrusions 204, which can further facilitate fixing the bracket 20 on the wall.

In the present embodiment, the groove on the electrical box 10 can include an annular shaped portion 12, wherein the connecting member 30 can rotatably penetrate through the annular shaped portion 12. The connecting member 30 can include two shrink rings 32 corresponding to the annular shaped portion 12 to limit a position of the connecting member 30 relative to the annular shaped portion 12. Therefore, the connecting member 30 can be connected to the electrical box 10, so that the connecting member 30 can rotate relative to the electrical box 10 when the mounting assembly works. It should be illustrated that the connecting member 30 in the present embodiment can be a long bolt. One of the two shrink rings 32 can be a bolt head of the long bolt, and annular shaped portion 12 can include an arc shaped groove matching with a smooth section of the long bolt.

In the present embodiment, the electrical box 10 can be provided with two sliding grooves 101. The bracket can be provided with two slipping sheets 102 corresponding to the two sliding grooves 101, and the bracket can be slidably mounted on the electrical box 10 via fitting between the two slipping sheets 102 and the two sliding grooves 101. Therefore, bracket 20 can slidably fit with the electrical box 10, so that the bracket 20 can slide relative to the electrical box 10 while fitting with the electrical box 10, thereby meeting a requirement of adjusting a mounting position between the bracket 20 and the electrical box 10.

In view of above, when a mounting assembly for an electrical box in the present disclosure works, the bracket 20 can be restrictively mounted on the power socket 10 with the connecting member 30, and the electrical box 10 can be fixed to the wall with the bracket 20.

When a mounting position of the electrical box 10 on the wall is to be adjusted, the mounting position of the electrical box 10 on the bracket 20 can be adjusted by screwing the connecting member 30, so as to meet different requirements.

The technical features of the above-described embodiments may be combined in any combination. For the sake of brevity of description, all possible combinations of the technical features in the above embodiments are not described. However, as long as there is no contradiction between the combinations of these technical features, all should be considered as within the scope of this disclosure.

The above-described embodiments are merely illustrative of several embodiments of the present disclosure, and the description thereof is relatively specific and detailed, but is not to be construed as limiting the scope of the disclosure. It should be noted that a number of variations and modifications may be made by one of ordinary skill in the art without departing from the spirit and scope of the disclosure. Therefore, the scope of the disclosure should be determined by the appended claims.

We claim:

1. A mounting assembly for an electrical box, comprising an electrical box, a bracket and a connecting member, the connecting member is configured for mounting the bracket on the electrical box,
wherein, the bracket is provided with a plurality of connecting protrusions at intervals, the electrical box is provided with a groove corresponding to the plurality of connecting protrusions; and,
the connecting member is accommodated in the groove of the electrical box, and a part of the connecting member in the groove successively penetrates through the plurality of connecting protrusions and is detachably fixed with the plurality of connecting protrusions.

2. The mounting assembly of claim 1, wherein the connecting member is provided with a thread protrusion, the connecting member is capable of driving the bracket to reciprocate relative to the electrical box by a cooperation between the plurality of connecting protrusions and the thread protrusion.

3. The mounting assembly of claim 1, wherein the bracket is provided with a limiting protrusion between adjacent two of the plurality of connecting protrusions, and both the limiting protrusion and the plurality of connecting protrusions abut against and surround the connecting member.

4. The mounting assembly of claim 1, wherein the plurality of connecting protrusions are a plurality of protruding plates, and the plurality of protruding plates are integrated with the bracket.

5. The mounting assembly of claim 1, wherein the number of the plurality of connecting protrusions is two.

6. The mounting assembly of claim 1, wherein the bracket comprises a body plate, the plurality of connecting protrusions are disposed on the body plate, the body plate extends towards a direction away from the electrical box and defines a fixing plate, wherein the fixing plate is provided with a fixing hole.

7. The mounting assembly of claim 6, wherein the fixing plate extends towards a direction away from the plurality of connecting protrusions and defines two hook plates, wherein the two hook plates are located at two sides of the fixing plate, respectively.

8. The mounting assembly of claim 6, wherein the body plate extends outwards relative to the electrical box and defines two mounting protrusions, and the two mounting protrusions are located at both sides of the electrical box, respectively, and wherein each of the two mounting protrusions is provided with a connecting hole.

9. The mounting assembly of claim 1, wherein the groove on the electrical box comprises an annular shaped portion, wherein the connecting member rotatably penetrates through the annular shaped portion, and the connecting member comprise two shrink rings corresponding to the annular shaped portion, to limit a position of the connecting member relative to the annular shaped portion.

10. The mounting assembly of claim 1, wherein the electrical box is provided with two sliding grooves, the bracket is provided with two slipping sheets corresponding to the two sliding grooves, and the bracket is slidably mounted on the electrical box via fitting between the two slipping sheets and the two sliding grooves.
